(19) United States
(12) Patent Application Publication
(10) Pub. No.: US 2008/0241385 A1
(43) Pub. Date: Oct. 2, 2008

(54) Method of Forming Thin Film, Thin Film Forming Apparatus, Program and Computer-Readable Information Recording Medium

(75) Inventors: Yasuhiro Oshima, Yamanashi (JP); Yasuhiko Kojima, Yamanashi (JP); Takashi Shigeoka, Yamanashi (JP); Hiroshi Kannan, Tokyo (JP); Tadahiro Ishizaka, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, TOKYO (JP)

(21) Appl. No.: 10/547,784

(22) PCT Filed: Feb. 26, 2004
(86) PCT No.: PCT/JP04/02243

§ 371 Date: May 7, 2007

(30) Foreign Application Priority Data
Mar. 4, 2003 (JP) 2003-057665

(51) Int. Cl. C23C 16/08; C23C 16/44

(52) U.S. Cl. 427/255.39; 118/715

(57) ABSTRACT

A method of rapidly forming a thin film of high quality through film formation by alternate feeding of raw gases. In particular, a method of forming a TiN thin film, comprising repeating operations including causing TiCl₄ gas as a raw gas to be adsorbed on a substrate or TiCl₄ molecules adsorbed on a substrate and feeding NH₃ gas as a reactant gas in a treating chamber so as to effect reaction of TiCl₄ and NH₃ leading to formation of a TiN film, which method further comprises an operation of, prior to the adsorption of TiCl₄ gas on the substrate, feeding reducing H₂ gas in the treating chamber (30) so as to change TiCl₄ to a state of enhanced likelihood of adsorption on the substrate (e.g., TiCl₃).

### FIELD OF THE INVENTION

The present invention relates to a method of forming a thin film, a thin film forming apparatus, a program and a computer-readable information recording medium; and, more particularly, to a method of forming a thin film and a thin film forming apparatus for performing a film formation by alternately providing source gases, a program for making a computer perform the method, and a computer-readable information recording medium for storing the program.

### BACKGROUND OF THE INVENTION

Recently, as semiconductor integrated circuits are getting smaller and more highly integrated, metal wiring films and insulation films formed on a substrate (e.g., a semiconductor substrate) need to be thinner, of high-quality without impurities, uniform macroscopically through the entire wafer, and smooth microscopically in the nanometer range. However, conventional chemical vapor deposition methods cannot fulfill one or more of the needs described above. There is presented a film forming method fulfilling these needs by alternately providing plural kinds of source gases, forming a film in a size of an atomic or molecular level through adsorbing source gases onto a substrate surface, and repeatedly carrying out these processes to obtain a thin film with a predetermined thickness.

More specifically, a first source gas is provided onto a substrate to form thereon an adsorbed layer. Thereafter, a second source gas is provided onto the substrate to make it react with the adsorbed layer. In this method, the first source gas is first adsorbed onto the substrate and then reacts with the second gas, thereby making it possible to lower a film-forming temperature. In addition, in case of forming a film in a hole, the deterioration in the coverage property in the conventional CVD methods caused by the fact that the source gas is consumed in an upper portion of the hole can be avoided.

Further, the thickness of the adsorbed layer, which usually corresponds to a single layer of atoms or molecules or two or three layers thereof at most, is determined by the temperature and pressure thereof. Therefore, if the source gas is provided excessively, the excessive gas other than the molecules adsorbed onto the substrate is discharged due to the self limitation of the adsorption, thereby making it easier to control a thickness of an extremely thin film. Besides, since the formation of the film is performed only once in an atomic or molecular level, the reaction is likely to be completed and impurities seldom remain in the film, which is preferable.

### SUMMARY OF THE INVENTION

Let us see a case where a TiN film is formed by the above-described method. In the case of forming a TiN film, titanium tetrachloride (TiCl₄) and ammonia (NH₃) are used as source gases.

A TiN film can be formed on a substrate by processing TiCl₄ and NH₃, for example, at a substrate temperature of 250-550° C. and a total pressure of 15-400 Pa.

However, since TiCl₄ is a thermally stable material, it is difficult to make it be adsorbed onto the substrate. When a thermally stable source gas, which is hard to be decomposed, is employed, an adsorbed amount of the gas onto the substrate surface is reduced so that the film-forming rate becomes unfavorably decreased.

The present invention is developed to overcome the aforementioned problems by providing a method for forming a film and a film forming apparatus capable of rapidly forming a high-quality thin film.

In overcoming the aforementioned problems, the present invention is characterized by providing the following process or method.

Specifically, the invention described in claim 1 provides a method of forming a thin film, comprising:

a first step of providing a source gas including an element serving as a source material of the thin film to be formed into a processing chamber to make the source gas be adsorbed onto a substrate or onto molecules of the source gas adsorbed on the substrate; and

a second step of providing the processing chamber with one or more kinds of reactive gases for reacting with the source gas to form the thin film and making the source gas react with the reactive gases to form a thin film layer,

wherein the thin film is formed by repeatedly performing the first step and the second step, and the method of forming the thin film further comprises:

a third step of changing the source gas into a state easy to be adsorbed onto the substrate before the source gas is adsorbed onto the substrate.

The invention described in claim 2 provides the method of claim 1, wherein, at the third step, the source gas is changed into the state easy to be adsorbed onto the substrate by activating the source gas.

The invention described in claim 3 provides the method of claim 1, wherein, at the third step, the source gas is reduced by means of a reduction gas.

The invention described in claim 4 provides the method of one of claims 1 to 3, wherein the source gas is made of metal halide or metal alkoxide.

The invention described in claim 5 provides the method of claim 3 or 4, wherein the source gas is made of titanium tetrachloride, the reactive gas is made of ammonia, and the reduction gas is made of hydrogen.

The invention described in claim 6 provides a thin film forming apparatus, comprising:

a first providing device for providing a source gas including an element serving as a source material of the thin film to be formed into a processing chamber; and

a second providing device for providing one or more kinds of reactive gases for reacting with the source gas to form the thin film into the processing chamber,

wherein the thin film is formed by repeatedly performing the step of providing the source gas by means of the first providing device and the step of providing the reactive gases by means of the second providing device, and the thin film forming apparatus further comprises:

a third providing device for providing a reduction gas into the processing chamber, wherein the reduction gas is provided into the processing chamber before or while the source gas is provided into the processing chamber.

The invention described in claim 7 provides the apparatus of claim 6, wherein the source gas is metal halide or metal alkoxide.

The invention described in claim 8 provides the apparatus of claim 6 or 7, wherein the source gas is titanium tetrachloride, the reactive gas is ammonia, and the reduction gas is hydrogen.

In accordance with the present invention, a source gas is rendered easy to be adsorbed onto a substrate before being adsorbed thereon, so that the rate at which the source gas is adsorbed onto the substrate is enhanced, and an adsorption density of the source gas increases to make it possible to form a uniform film.

Other features and effects of the present invention will become apparent from the following description of preferred embodiments, given in conjunction with the accompanying drawings.

### BRIEF DESCRIPTION OF THE DRAWINGS

FIG. 1 shows a configuration of a thin film forming apparatus in accordance with an embodiment of the present invention.

FIG. 2 presents a flow chart representing a thin film forming method in accordance with an embodiment of the present invention.

FIG. 3 provides a timing chart illustrating valve opening/closing timings in case of performing a thin film forming method in accordance with an embodiment of the present invention.

FIG. 4 depicts a relationship between a pressure in a processing chamber and an adsorbed amount of TiCl₄ on a substrate.

FIG. 5 is presented for explaining an effect of the present invention.

FIG. 6 represents applicable examples of the present invention.

### DETAILED DESCRIPTION OF THE PREFERRED EMBODIMENT

Hereinafter, an embodiment of the present invention will be described together with the drawings.

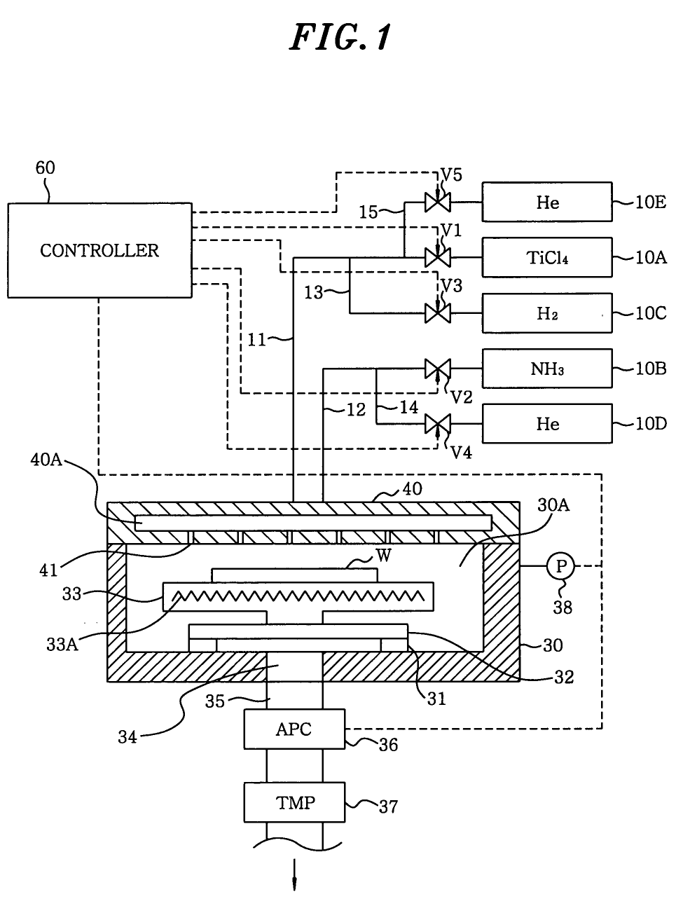

FIG. 1 shows a thin film forming apparatus in accordance with an embodiment of the present invention. In this embodiment, a CVD apparatus is shown as an example of the thin film forming apparatus. As a whole, the thin film forming apparatus shown in FIG. 1 includes gas supply sources 10A-10E, a processing chamber 30, a susceptor 33, and a controller 60.

The gas supply sources 10A-10E provide source gases described later and the like into the processing chamber 30 via gas passages 11-15. That is, the gas supply sources 10A-10E respectively provide a semiconductor wafer W in the processing chamber 30 with gases for performing a predetermined film forming process.

The thin film forming apparatus in accordance with the embodiment forms a titan nitride (TiN) film by using a chemical vapor deposition method. To be more specific, in this embodiment, a TiN film is formed by a reaction between a titanium tetrachloride (TiCl₄) gas serving as a source gas and an ammonia (NH₃) gas serving as a reactive gas. Further, as will be described later, in this embodiment, it is configured such that a hydrogen (H₂) gas is also provided into the processing chamber 30 as a reduction gas.

The gas supply source 10A provides the TiCl₄ gas into the processing chamber 30 via the gas passage 11. In the gas passage 11 is installed a valve V1, and thus the flow of the TiCl₄ gas can be controlled by opening/closing of the valve V1. In addition, the temperature in the gas passage 11 can be controlled such that it can be heated to be kept at a predetermined temperature, for example, 120° C. Furthermore, the operation of the valve V1 is controlled by the controller 60 described later.

The gas supply source 10B provides the NH₃ gas into the processing chamber 30 via the gas passage 12. In the gas passage 12 is installed a valve V2, and thus the flow of the NH₃ gas can be controlled by opening/closing of the valve V2. In addition, the operation of the valve V2 can be also controlled by the controller 60 described later.

Further, the gas supply source 10C provides the H₂ gas serving as a reducer into the processing chamber 30 via the gas passage 13. A valve V3 is installed in the gas passage 13 in such a way that it communicates with the gas passage 11 connected to the gas supply source 10A. The flow of the H₂ gas can be controlled by opening/closing of the valve V3. In addition, the operation of the valve V3 can be also controlled by the controller 60 described later.

The gas supply sources 10E and 10D provide a helium (He) gas, which is an inert gas, as a carrier gas. The gas supply source 10E is connected to the gas passage 11 via the gas passage 15.

In the gas passage 15 is installed a valve V5 controlled by the controller 60. Further, the gas supply source 10D is connected to the gas passage 12 via the gas passage 14. In the gas passage 14 is installed a valve V4 controlled by the controller 60.

The processing chamber 30 is formed of metal such as aluminum (Al) or stainless steel, and, in case of using Al, a surface treatment such as an alumite treatment is performed. The processing chamber 30 includes a susceptor 33 which supports the wafer W that is an object to be processed, wherein the susceptor 33 is made of ceramic material such as AlN or Al₂O₃ and has a heater 33A buried therein. The susceptor 33 is fixed on a bottom portion of the processing chamber 30 by susceptor supporting components 31 and 32.

On the bottom portion of the processing chamber 30 is installed a gas exhaust port 34 connected to a gas exhaust line 35. In addition, to the gas exhaust line 35 is connected a turbo molecular pump 37 serving as an exhausting device which is configured such that the inside of the processing chamber can be vacuum pumped. Furthermore, in the gas exhaust line 35 is installed an APC (auto pressure control unit) 36 for controlling pressure in the processing chamber 30 by changing a conductance thereof.

Besides, on a side portion of the processing chamber 30 is installed a pressure gauge 38 for measuring pressure in the processing chamber. It is configured such that the pressure measurement obtained by the pressure gauge 38 is sent to the controller 60. In other words, it is configured such that, by feedbacking the pressure measurement obtained by the pressure gauge 38 to the controller 60, the controller 60 can adjust the conductance of the APC 36 to control the pressure in the processing chamber 30 to be kept at a desired value.

Further, on an upper portion of the processing chamber 30 is installed a shower head 40 having a diffusion area 40A. To the diffusion area 40A is connected the gas passages 11 and 12.

The controller 60, which includes a computer, is connected to the respective valves V1 to V5. The controller 60 controls the opening/closing of the respective valves V12-V5 in accordance with a film-forming process program described later, thereby making it possible to fabricate a high-quality TiN film.

Furthermore, besides the valves V1-V5, the controller 60 also controls devices included in the thin film forming apparatus (e.g., the valve 36 and the vacuum pump 37). However, in the following, the description will be given mainly about the valves V1-V5, which are main parts of this embodiment.

In the following, a method of forming a TiN film, which is performed by using the thin film forming apparatus shown in FIG. 1, will be explained.

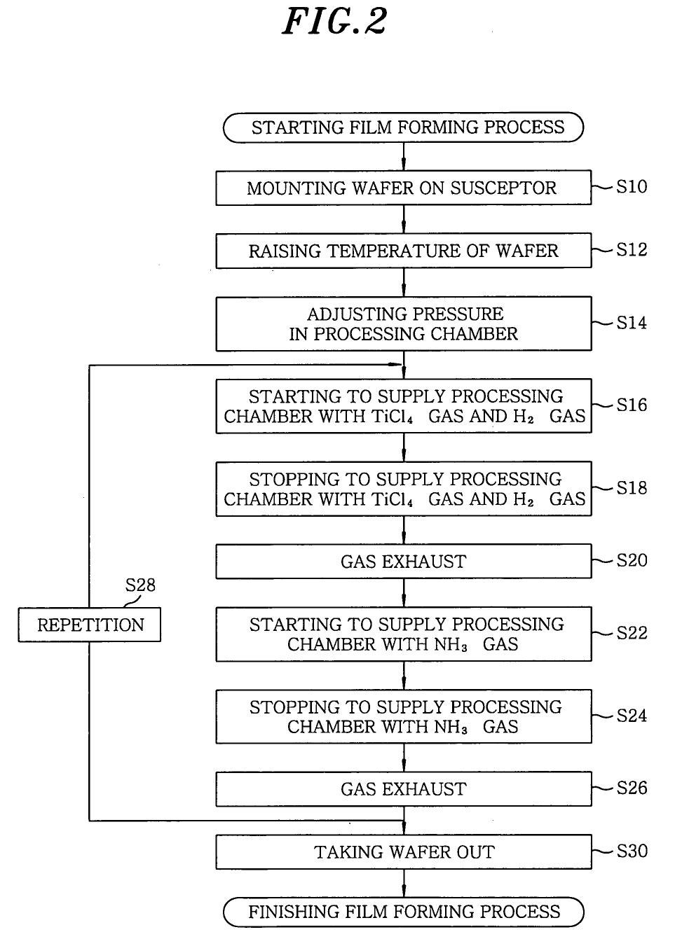

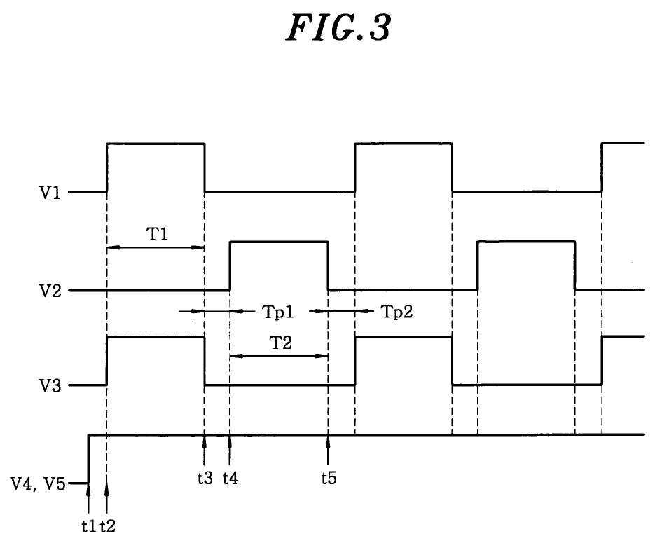

FIG. 2 is a flow chart representing a thin film forming method of forming a TiN film in accordance with a first embodiment of the present invention, and FIG. 3 is a timing chart illustrating opening/closing timings for valves V1-V5 in case of performing a thin film forming method in accordance with this embodiment.

For forming a TiN film, firstly at step 10 (“step” is abbreviated as “S” in the drawings), the wafer W is mounted on the susceptor 33. The susceptor 33 is heated by the heater 35 to thereby heat the wafer W mounted thereon. In this embodiment, the wafer W can be heated to be kept at a temperature in the range of 250-550° C. (step 12).

Thereafter, the controller 60 opens the valve V4 and V5 (at a timing t1 in FIG. 3). Accordingly, the He gas is supplied to the processing chamber 30 as the carrier gas from the gas supply sources 10D and 10E and the controller 60 controls the operation of the vacuum pump 37 by controlling the APC 36 such that the inside of the processing chamber 30 is exhausted to be kept at a pressure, e.g., 200 Pa as a total pressure (step 14).

It is configured such that the temperature of the susceptor 33 and the pressure in the processing chamber 30 are detected by respective sensors, which are not shown, and then the measurement results are sent to the controller 60. In addition, if it is judged that the temperature of the wafer W and the pressure in the processing chamber 30 have been reached predetermined levels, the controller 60 opens the valve V1 and the valve V3 at step 16 (at a timing t2).

Thus, the TiCl₄ gas, together with the He gas serving as the carrier gas, is provided from the gas supply source 10A to the processing chamber 30 via the gas passage 11. Further, since the valve V3 is opened together with the valve V1 as described above, the H₂ gas serving as a reduction gas is provided from the gas supply source 10C to the processing chamber 30 together with the TiCl₄ gas serving as a source gas.

The TiCl₄ gas and the H₂ gas are provided to the processing chamber 30 during a predetermined period of time (a period of time designated by an arrow T1 in FIG. 3 which is, e.g., 10 seconds). Then, after the period of time T1 has been elapsed, the controller 60 closes the valves V1 and V3 (step 18; at a timing t3). Accordingly, the gas supply source 10A ceases to provide the TiCl₄ gas to the processing chamber 30 and the gas supply source 10C ceases to provide the H₂ gas. During the period of time T1, TiCl₄ is adsorbed onto the surface of the wafer W. Further, in the above process, the supplied amount of TiCl₄ is, for example, 30 sccm, that of He is, for example, 200 sccm, and that of H₂ is, for example, 100 sccm.

However, since the TiCl₄ gas is a thermally stable material as described above, it is difficult to decompose it by only applying a thermal process. Because of this, as described above, in case where only the TiCl₄ gas in a stable state is provided into the processing chamber 30, the adsorbed amount on the wafer W is small, and thus the film-forming rate of the TiN film is low.

In contrast, in this embodiment, the TiCl₄ gas serving as a source gas is provided to the processing chamber 30 together with the H₂ gas serving as the reduction gas. As a result, TiCl₄ reacts with H₂ so that, by a reduction of the TiCl₄, state transitions are taken place as described by Eqs. 1 and 2.

2TiCl₄+H₂→(TiCl₃)⁺+2HCl Eq. (1)

TiCl₄+H₂→(TiCl₂)⁺⁺+2HCl Eq. (2)

As seen above, by the reduction of TiCl₄, a monovalent ion (TiCl₃)⁺ or a bivalent ion (TiCl₂)⁺⁺ is formed. Since (TiCl₃)⁺ and (TiCl₂)⁺⁺ are activated by ionization, an adsorptive force onto the wafer W is higher compared to the case of using TiCl₄.

Here, let us observe the composition ratio of each of TiCl₄, (TiCl₃)⁺ and (TiCl₂)⁺⁺.

In the conventional method of forming a thin film where the reducer (H₂ gas) is not used, the most abundant is TiCl₄, which has a high thermal stability so that it cannot be easily adsorbed onto the wafer W. On the other hand, the composition ratios of (TiCl₃)⁺ and (TiCl₂)⁺⁺, which can be easily adsorbed to the wafer W, are low. To be more specific, the respective composition ratios of TiCl₄, (TiCl₃)⁺ and (TiCl₂)⁺⁺ are such that [TiCl₄]>[(TiCl₃)⁺]>[(TiCl₂)⁺⁺].

On the contrary, in this embodiment, the TiCl₄ gas is provided into the processing chamber 30 together with the H₂ gas serving as the reducer, thereby resulting in the reduction reactions described in Eqs. (1) and (2) to generate in a large amount (TiCl₃)⁺ and (TiCl₂)⁺⁺ having a strong adsorptive force onto the wafer W compared to TiCl₄. To be more specific, the respective composition ratios of TiCl₄, (TiCl₃)⁺ and (TiCl₂)⁺⁺ are such that [(TiCl₃)⁺]>[(TiCl₂)⁺⁺]>[TiCl₄].

As described above, in this embodiment, the TiCl₄ gas, which is the source gas, is provided to the processing chamber 30 together with the H₂ gas, which is the reduction gas, so that the processing chamber contains a large amount of (TiCl₃)⁺ and (TiCl₂)⁺⁺, each having a strong adsorptive force onto the wafer W. Therefore, (TiCl₃)⁺ and (TiCl₂)⁺⁺ become adsorbed onto the entire surface of the wafer W in a short time.

Further here, let us observe the respective volumes per molecule of TiCl₄, (TiCl₃)⁺ and (TiCl₂)⁺⁺. TiCl₄ has a structure where four Cl atoms are attached to a single Ti atom, (TiCl₃)⁺ has a structure where a single chlorine atom is detached from TiCl₄, and (TiCl₂)⁺⁺ has a structure where two chlorine atoms are detached from TiCl₄. As a result, TiCl₄ occupies the greatest volume and the volume of each molecule is in the order of TiCl₄, (TiCl₃)⁺ and (TiCl₂)⁺⁺.

In the conventional method, materials adsorbed onto the wafer W were mostly TiCl₄ which occupies a large volume so that the number of TiCl₄ adsorbed onto the wafer (i.e., the number of Ti atoms) tended to be small. On the contrary, in this embodiment, (TiCl₃)⁺ and (TiCl₂)⁺⁺ which have smaller volumes compared with TiCl₄, become adsorbed onto the wafer W so that adsorption density of the molecules gets high, thereby increasing the number of (TiCl₃)⁺ and (TiCl₂)⁺⁺ adsorbed onto the wafer (i.e., the number of Ti atoms) compared to the conventional case.

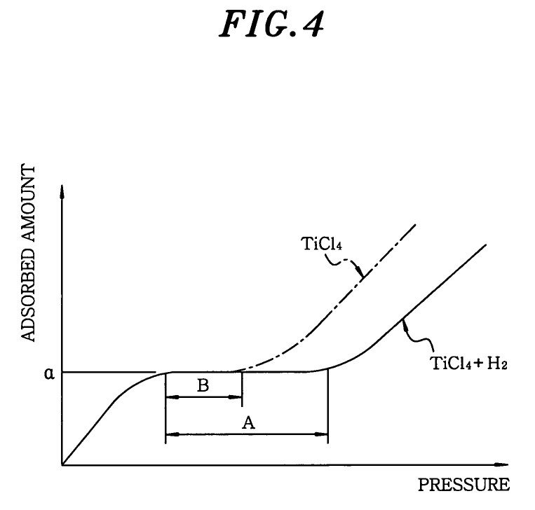

FIG. 4 presents the BET (Brunaner, Emmett and Teller) adsorption isotherm based on this embodiment. In FIG. 4, the horizontal axis represents the pressure in the processing chamber 30 and the vertical axis represents the adsorbed amount of the materials adsorbed onto the wafer W i.e., TiCl₄, (TiCl₃)⁺ and (TiCl₂)⁺⁺. Further, in FIG. 4, a solid line represents the characteristic of the case where the H₂ gas is provided to the processing chamber 30 together with the TiCl₄ gas by the method of this embodiment; and a dotted line represents the characteristic of the case where only the TiCl₄ gas is provided to the processing chamber 30 by the conventional method. In addition, the adsorbed amount a shown therein is the adsorbed amount in case where the materials are adsorbed onto the entire surface of the wafer W.

As shown therein, it can be seen that the range where the adsorbed amount is a in this embodiment (the range designated by an arrow A in the drawing) is wider than the range where the adsorbed amount is a in the conventional method (the range designated by an arrow B in the drawing), i.e., A>B. This is because, in this embodiment, (TiCl₃)⁺ and (TiCl₂)⁺⁺ respectively having stronger adsorptive forces than TiCl₄ are adsorbed onto the wafer W in a large amount so that, even if the pressure in the processing chamber 30 changes, the adsorptions of preferable quantity can take place over a wide range of pressure.

As described above, since the adsorption of good quantity can be performed over a wide range of pressure in this embodiment, it is possible to carry out a process of forming a uniform film. In the following, the reason thereof will be explained.

As shown in FIG. 1, the processing chamber 30 contains various kinds of components. In addition, although the flow rate of each kind of gases provided into the processing chamber 30 through the shower head 20 is adjusted to be uniform, the actual distribution of the gases provided on the wafer W becomes non-uniform. Because of this and the like, it is difficult to make the flow rates of gases provided onto the wafer W uniform, resulting in a non-uniform pressure distribution.

If the range B where adsorption of good quantity can be performed is narrow as in the conventional case (see FIG. 4), the adsorbed amount becomes different from part to part of the wafer W due to the pressure differences thereon. To be more specific, there will be resulted in adsorption spots on the wafer W; that is, the materials to be adsorbed (TiCl₄, (TiCl₃)⁺ and (TiCl₂)⁺⁺) are very well adsorbed onto some areas on the wafer W whereas the materials are poorly adsorbed onto some other areas. When the adsorption spots occur, the desired TiN film with good uniformity cannot be formed.

On the contrary, in this embodiment, the range A where the adsorption of good quantity can be performed is wide such that the resulting differences in the adsorbed amount can be curbed even when there may be some differences in the pressure on the wafer W.

Back to FIGS. 2 and 3, the explanation thereof shall be resumed in the following. After the materials to be adsorbed (mainly (TiCl₃)⁺ and (TiCl₂)⁺⁺) are adsorbed onto the wafer W in a short time and in a uniform manner through the processes of step 16 and step 18, the controller 60 opens the valve in the APC 36 further to thereby increase the pumping force of the vacuum pump 42.

Thereby, the H₂ gas serving as the reducer and the unadsorbed part of the TiCl₄ gas remaining in the processing chamber are exhausted from the processing chamber 30 (step 20). This exhausting process is carried out, e.g., for two seconds (the period of time Tp1 designated by arrows). After this period of time has elapsed, the controller 60 reverses the opening of the valve 36 to its original position.

After the exhausting process of step 20 has been completed, the controller 60 opens the valve V2 (at a timing t4). Accordingly, the NH₃ gas is provided into the processing chamber 30 from the gas supply source 10B via the gas passage 12 (step 22).

At this time, the materials to be adsorbed (mainly (TiCl₃)⁺ and (TiCl₂)⁺⁺) are uniformly adsorbed onto the wafer W through the processes of step 16 and step 18. Further, there is no residue of TiCl₄ left in the processing chamber 30 after performing the process of step 20. Because of this, the adsorbed materials (mainly (TiCl₃)⁺ and (TiCl₂)⁺⁺) adsorbed onto the wafer W rapidly reacts with the NH₃ gas (nitridation).

The supply of the NH₃ gas into the processing chamber 30 is carried out for a predetermined period of time (the period of time designated by an arrow T2 in FIG. 3; for example, 10 seconds). During this time, the supplied amounts of NH₃ and He are, e.g., 800 sccm and 200 sccm, respectively. After this period of time, the valve V2 is closed at a timing t5).

During this period of time, the adsorbed materials (mainly (TiCl₃)⁺ and (TiCl₂)⁺⁺) adsorbed onto the wafer W react with the supplied NH₃ gas to form a TiN film. Herein, since thus formed thin TiN film is formed by the nitridation of the adsorbed materials adsorbed during step 16 and step 18 (mainly (TiCl₃)⁺ and (TiCl₂)⁺⁺), it is a thin film of thickness in a molecular/atomic level.

Thereafter, the controller 60 opens the valve in the APC 36 further to increase the pumping force of the vacuum pump 42 again. Thus, the unreacted part of the NH₃ gas remaining in the processing chamber 30 is exhausted from the processing chamber 30 (step 26). This exhausting process is carried out, for example, for two seconds (the period of time Tp2 designated by arrows in FIG. 3). After this period of time has elapsed, the controller 60 reverses the change in the opening of the valve in the APC 36 to its original position.

Afterwards, the controller 60 performs step 28 to reverse the process back to step 16, and then the processes from step 16 to step 26 are carried out repeatedly for a predetermined number of times (e.g., 200 times). In the second or subsequent turn of step 16 and step 18, the materials to be adsorbed (mainly (TiCl₃)⁺ and (TiCl₂)⁺⁺) are adsorbed onto the TiN film, which is formed as a lower layer.

Also in the second or subsequent turn of step 16 and step 18, TiCl₄, which is the source gas, is provided into the processing chamber 30 together with H₂ serving as the reducer so that, even in the second or subsequent process for adsorption, the materials mainly adsorbed are (TiCl₃)⁺ and (TiCl₂)⁺⁺, which have respectively stronger adsorptive forces and smaller volumes than TiCl₄.

Therefore, the adsorption density and adsorption rate of the adsorbed materials (mainly (TiCl₃)⁺ and (TiCl₂)⁺⁺) are higher than those of TiCl₄. As a result, even in the second or subsequent turn, the adsorbed materials (mainly (TiCl₃)⁺ and (TiCl₂)⁺⁺) are adsorbed onto the wafer W (more particularly, on the TiN film which forms the lower layer) rapidly and uniformly.

After the TiN film of a desired thickness has been formed by performing the processes from step 16 to step 26 repeatedly for a predetermined number of times, the process moves on to step 30. The controller 60, at step 30, closes the valves V4 and V5 to stop the He gas (carrier gas) being supplied from the gas supply sources 10D and 10E into the processing chamber 30.

Subsequently, the wafer having a TiN film formed thereon is taken out. By performing the series of the processes as described above, a preferable TiN film can be formed on the wafer W rapidly.

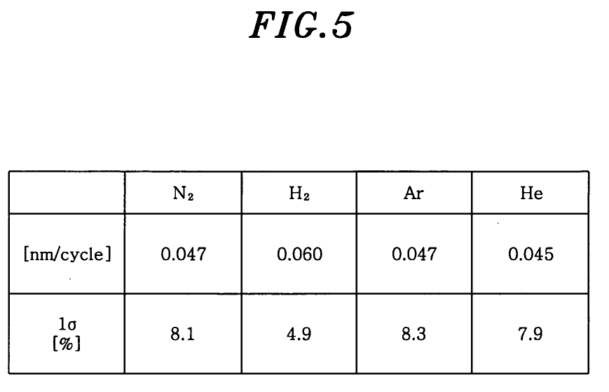

FIG. 5 presents the measured values of the growth rate and the surface uniformity 1σ of the TiN film formed as described above. The growth rate of the TiN film is represented by the thickness of the TiN film formed during a single cycle, wherein a single cycle is defined as the processes from step 16 to step 26. Therefore, the unit of the growth rate is nm/cycle.

Further, the film thickness uniformity of the TiN film is represented by a standard deviation (the unit is per cent). To be more specific, it is obtained by measuring the film thickness of the TiN film formed on the wafer W, whose diameter is 200 mm, at a number of points, computing the square values of the deviations from the mean film thickness at the measured points, dividing the added amount of these square values at all the points by the number of measurements, and then calculating the square root thereof. Therefore, a smaller value of the film thickness uniformity 1σ represents a more uniform state.

Furthermore, as comparative examples, FIG. 5 describes the growth rate of the TiN film together with the film thickness uniformity 1σ in case where the N₂ gas, the Ar gas and the He gas are respectively provided in place of the H₂ gas serving as the reducer as characterized in this embodiment.

Observing the growth rate of the TiN film, we can see that it is the highest (0.060 nm/cycle) in case where the reducer (H₂ gas) for this embodiment is provided into the processing chamber 30 together with TiCl₄. Further, observing the film thickness uniformity 1σ in the TiN film, we can see that it is the lowest (4.9%) and therefore the TiN film has the most uniform thickness in case where the reducer (H₂ gas) for this embodiment is provided into the processing chamber 30 together with TiCl₄. The results shown in FIG. 5 prove that a thin film can be formed rapidly with uniform thickness by the film forming method of this embodiment.

In the above embodiment, it has been described as to the case where the present invention is applied to the method of forming a TiN film by causing a reaction between TiCl₄ (the source gas) and NH₃ (the reactive gas). However, the present invention is not limited thereto but applicable to various kinds of film-formings. Further, although He has been used as the carrier gas in this embodiment, Ar or N₂ can be used in lieu of this. Still further, the exhausting process of step 20 and step 26 in this embodiment shown in FIG. 2 can also be configured such that the supply of He is stopped to vacuum pump.

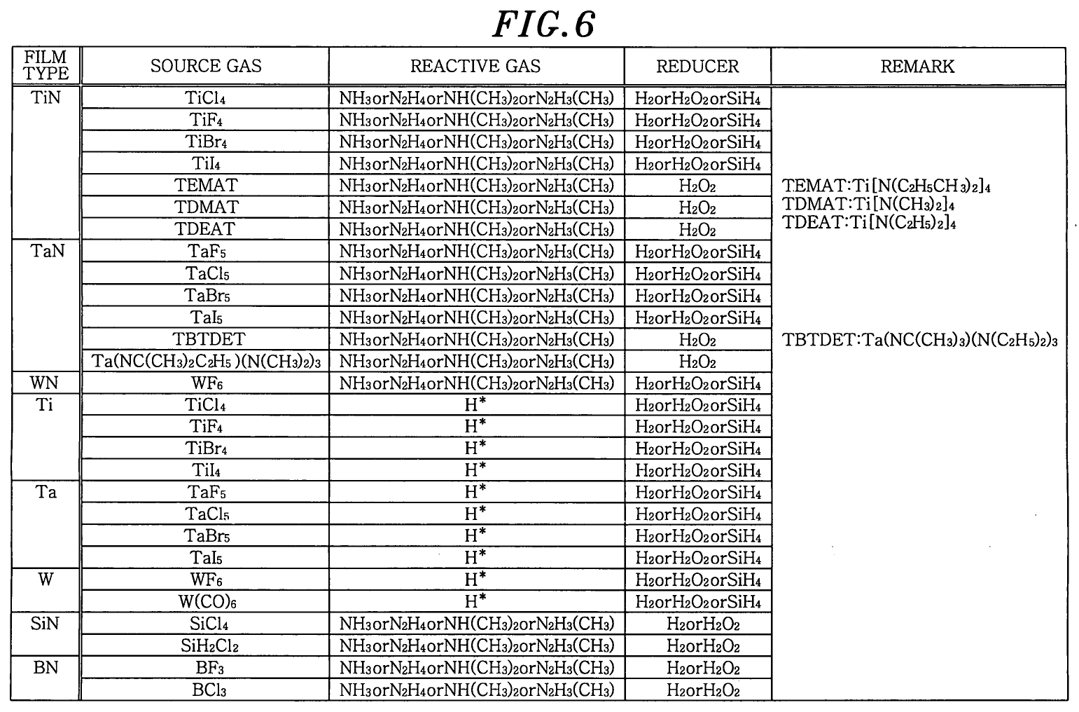

FIG. 6 describes some combinations of a source gas, a reactive gas and a reducer, applicable to the present invention. As shown therein, metal halides or metal alkoxides can be used as the source gas. Further, the present invention can be applied to forming such various kinds of films as a TiN film, a TaN film, a WN film, a Ti film, a Ta film, a TaCN film, a W film, a SiN film, and a BN film.

Furthermore, the controller shown in FIG. 1 can include a computer. In this case, it is possible to make up a program including the commands for making the computer perform the method of forming a thin film in accordance with the embodiment of the present invention together with FIG. 2 and carry out the present invention as described above by reading and running the program with the CPU in the computer. In this case, the program can be inputted to the computer from outside via a portable-type computer-readable information recording medium such as a CD-ROM, or can be inputted to the computer connected to a communication network such as internet or LAN from an external server via the network.

Besides, various kinds of embodiments can be implemented within the scope disclosed in the accompanying claims.

What is claimed is:

1. A method of forming a thin film, comprising:
a first step of providing a source gas including an element serving as a source material of the thin film to be formed into a processing chamber to adsorb the source gas onto a substrate or onto molecules of the source gas adsorbed on the substrate; and
a second step of providing the processing chamber with one or more kinds of reactive gases for reacting with the source gas to form the thin film and making the source gas react with the reactive gases to form a thin film layer,
wherein the thin film is formed by repeatedly performing the first step and the second step, and
the method of forming the thin film further comprising:
a third step of changing the source gas into a state easy to be adsorbed onto the substrate before the source gas is adsorbed onto the substrate.

2. The method of claim 1, wherein, at the third step, the source gas is changed into the state easy to be adsorbed onto the substrate by activating the source gas.

3. The method of claim 1, wherein, at the third step, the source gas is reduced by a reduction gas.

4. The method of claim 1, wherein the source gas is metal halide or metal alkoxide.

5. The method of claim 3, wherein the source gas is titanium tetrachloride, the reactive gas is ammonia, and the reduction gas is hydrogen.

6. A thin film forming apparatus, comprising:
a first providing device for providing a source gas including an element serving as a source material of the thin film to be formed into a processing chamber; and
a second providing device for providing one or more kinds of reactive gases for reacting with the source gas to form the thin film into the processing chamber,
wherein the thin film is formed by repeatedly performing the step of providing the source gas by means of the first providing device and the step of providing the reactive gases by means of the second providing device, and
the thin film forming apparatus further comprising:
a third providing device for providing a reduction gas into the processing chamber, wherein the reduction gas is provided into the processing chamber before or while the source gas is provided into the processing chamber.

7. The apparatus of claim 6, wherein the source gas is metal halide or metal alkoxide.

8. The apparatus of claim 6, wherein the source gas is made of titanium tetrachloride, the reactive gas is made of ammonia, and the reduction gas is made of hydrogen.

9. A program comprising commands for a computer to perform the steps of claim 1.

10. A program comprising commands for a computer to perform the steps of claim 2.

11. A program comprising commands for a computer to perform the steps of claim 3.

12. A computer-readable information recording medium for storing the program of claim 9.

13. A computer-readable information recording medium for storing the program of claim 10.

14. A computer-readable information recording medium for storing the program of claim 11.
